(19) United States
(12) Patent Application Publication
(10) Pub. No.: US 2016/0365262 A1
(43) Pub. Date: Dec. 15, 2016

(54) SEMICONDUCTOR FABRICATION FACILITY DATA COLLECTION SYSTEM

(71) Applicant: Haws Corporation, Sparks, NV (US)

(72) Inventor: Benjamin R. Peek, Beaverton, OR (US)

(21) Appl. No.: 14/740,077

(22) Filed: Jun. 15, 2015

(51) Int. Cl. H01L 21/67

(52) U.S. Cl. CPC H01L 21/67253; H01L 21/67017; H01L 21/67288

(57) ABSTRACT

A system and method for collecting and analyzing real-time data generated by different semiconductor fabrication tools in a semiconductor fabrication facility, and allowing a user to access said data remote from the semiconductor fabrication facility.

### BACKGROUND

The percentage of yield in a semiconductor fabrication facility lost to random defects is mostly due to contamination. In modern fabrication facilities using sub-0.5 micro design rules, 40-50% of the total yield loss in the first year of production can be attributed to random defects. Furthermore, as semiconductors become smaller and wafer sizes become larger, smaller defects can cause exponentially lower yields.

Contamination can result from all aspects of semiconductor manufacturing, including: processes, equipment, fluid storage, and fluid supply. To reduce contamination and other defects in semiconductor manufacturing facilities, every process and piece of equipment should be monitored and maintained such that contaminations are minimized or detected and eliminated quickly.

Short production lifecycles and the introduction of new products with short time constraints result in many fabrication facilities utilizing batch production. Batch production facilities use the fabrication equipment to produce different products. This often requires the fabrication facility to shut down, reconfigure, and test its fabrication equipment. During shut down, the fabrication facility cannot operate. To reduce the downtime between equipment testing and reconfiguration, every process and piece of equipment should be monitored and maintained such that downtime is minimized.

A data collection system is needed that monitors and reports in real-time the operating status of one or more pieces of equipment in the semiconductor fabrication facility and can be implemented with any piece of equipment or process used in the fabrication facility.

### SUMMARY

Solutions to improve semiconductor fabrication facility efficiency have been realized and are described herein.

In some embodiments, a fabrication data collection system includes a semiconductor tool data collection unit that includes a data collector, a semiconductor fabrication tool, an energy monitor and a fluid flow monitor. The semiconductor fabrication tool can include internal and/or external sensors to output certain tool characteristics (e.g. motor current, tool temperature, and copper radioactivity). The energy monitor can be configured to output the amount of energy used by the semiconductor fabrication tool. The fluid flow monitor can be configured to output the fluid flow rate of liquids or gases used by the semiconductor fabrication tool. The data collector can be configured to collect the outputs and communicate the received outputs to one or more servers via a network switch. The servers, and possibly the data collector, can be configured to perform analysis on received information from the semiconductor tool, the energy monitor, the fluid flow monitor and other various sensors and monitors. The servers, and possibly the data collector can be configured to store the results of the analysis. In some cases, the servers are configured to connect to a public network through a secure firewall, such that one or more authorized users are able to remotely access information stored on the servers though a public network.

### BRIEF DESCRIPTION OF THE VARIOUS VIEWS OF THE DRAWINGS

FIG. 1 is an illustration of an embodiment of a semiconductor fabrication tool data collection system.

FIG. 2 is an illustration of an embodiment of an analysis display of the semiconductor fabrication tool data collection system.

FIG. 3 is a flow diagram illustrating an embodiment of events in accordance with the operation of the semiconductor fabrication tool data collection system.

FIG. 4 is a block diagram illustration of one embodiment of a data collector of the semiconductor fabrication data collection system.

### DETAILED DESCRIPTION OF THE ILLUSTRATED EMBODIMENTS

### I. Definitions of Terms

Certain terms used in connection with exemplary embodiments are defined below.

As used herein, the term “effluent” and similar terms are defined as a liquid, solid, or gaseous emission, such as the discharge or outflow from a machine or an industrial process.

As used herein, the term “monitoring” and similar terms are defined as a device or arrangement for observing, detecting, sensing, or recording the operation of a machine or system.

As used herein, the terms “semiconductor facility tool,” “semiconductor facility equipment,” “tool,” and similar terms are defined as any equipment, device, object, or physical element used in the manufacture of a semiconductor.

As used herein, the term “analysis” and similar terms are defined as the process of optimizing the functionality of the whole semiconductor fabrication facility and/or individual semiconductor equipment by looking at data from one or more sources.

As used herein the terms “properties,” “characteristics,” and similar terms may be used interchangeably to refer to features, qualities, attributes, properties, components, nature, characteristics, and the like belonging to a corresponding object.

As used herein, the terms “data,” “content,” “information,” and similar terms may be used interchangeably to refer to data capable of being transmitted, received, and/or stored in accordance with embodiments of the present invention. Thus, use of any such terms should not be taken to limit the spirit and scope of embodiments of the present invention. Further, where a module, processor or device is described herein to receive data from another module, processor or device, it will be appreciated that the data may be received directly from the another module, processor or device or may be received indirectly via one or more intermediary modules or devices, such as, for example, one or more servers, relays, routers, network access points, base stations, hosts, and/or the like, sometimes referred to herein as a “network.” Similarly, where a computing device is described herein to send data to another computing device, it will be appreciated that the data may be sent directly to the another computing device or may be sent indirectly via one or more intermediary computing devices, such as, for example, one or more servers, relays, routers, network access points, base stations, hosts, and/or the like.

As used herein, the term “module,” encompasses hardware, software and/or firmware configured to perform one or more particular functions.

As used herein, the term “computer-readable medium” refers to a non-transitory storage hardware, non-transitory storage device or non-transitory computer system memory that may be accessed by a controller, a microcontroller, a computational system or a module of a computational system to encode thereon computer-executable instructions or software programs. A “non-transitory computer-readable medium” may be accessed by a computational system or a module of a computational system to retrieve and/or execute the computer-executable instructions or software programs encoded on the medium. A non-transitory computer-readable medium may include, but is not limited to, one or more types of non-transitory hardware memory, non-transitory tangible media (for example, one or more magnetic storage disks, one or more optical disks, one or more USB flash drives), computer system memory or random access memory (such as, DRAM, SRAM, EDO RAM), and the like.

As used herein, the term “set” refers to a collection of one or more items.

As used herein, the term “plurality” refers to two or more items.

As used herein, the terms “equal” and “substantially equal” refer interchangeably, in a broad lay sense, to exact equality or approximate equality within some tolerance.

As used herein, the terms “similar” and “substantially similar” refer interchangeably, in a broad lay sense, to exact sameness or approximate similarity within some tolerance.

As used herein, the terms “couple” and “connect” encompass direct or indirect connection among two or more components. For example, a first component may be coupled to a second component directly or through one or more intermediate components.

Some exemplary embodiments of the present invention will now be described more fully hereinafter with reference to the accompanying drawings in which some, but not all, embodiments of the inventions are shown. Indeed, these inventions may be embodied in many different forms and should not be construed as limited to the embodiments set forth herein. Like numbers refer to like elements throughout.

### II. Illustrative Embodiments

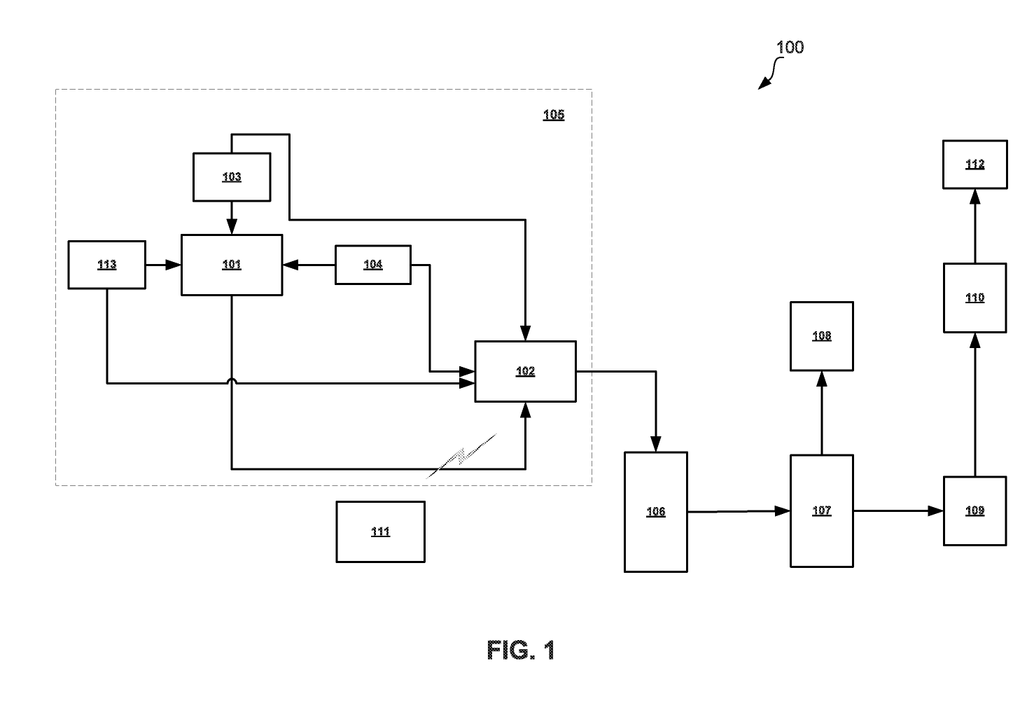

FIG. 1 shows a schematic diagram of an exemplary semiconductor fabrication tool data collection system. Semiconductor fabrication tool data collection system 100 may detect, monitor, store, and utilize information gathered from various parts of a semiconductor fabrication facility. Parts of a semiconductor fabrication facility may include: any semiconductor fabrication tool (e.g. Chemical-Mechanical Planarization tools, Chemical Vapor Deposition tools, Physical Vapor Deposition tools, cleaning tools, etching tools, lithography tools, polishing tools, lapping tools, and the like); tool and fabrication facility liquid and gas supply lines and storage containers; effluent from any semiconductor fabrication tool, effluent from the semiconductor fabrication facility; and any element, object, tool, or process implemented in a semiconductor fabrication facility.

Semiconductor fabrication tool data collection system 100 may include one or more semiconductor fabrication tools. Tool 101 (e.g. a Chemical-Mechanical Planarization tool) may include one or more sensors (not shown). Sensors may be provided by the equipment manufacturer or an entity that performs maintenance on the tool. The sensors may, in real-time or at a predetermined time interval, detect characteristics of the tool. The detected characteristics will vary depending on the tool. For example, if tool 101 is a Chemical-Mechanical Planarization tool, then detected characteristics may include: motor current, tool temperature, and copper radioactivity. Tool 101 may, in real-time or at a predetermined time interval, output the detected characteristics to data collector 102 using a wireless or wired connection.

Energy monitor 103 may be coupled to both tool 101 and data collector 102 using a wired or wireless connection. Energy monitor 103 may be implemented by any standard computer equipment including but not limited to: a computer, a field programmable gate array, application specific integrated circuit, and the like. Energy monitor 103 may, in real-time or at a predetermined time interval, detect energy and/or power utilized by the tool during, before, and/or after operation. Energy monitor 103 may, in real-time or at a predetermined time interval, output the detected power and/or energy usage to data collector 102 using a wireless or wired connection.

Fluid flow monitor 104 may be coupled physically to tool 101. Fluid flow monitor 104 may be implemented by any standard computer equipment including but not limited to: a computer, a field programmable gate array, application specific integrated circuit, and the like. Fluid flow monitor 104 may, in real-time or at a predetermined time interval, detect the fluid flow rate of liquids or gases utilized by the tool during, before, and/or after operation. Fluid flow monitor 104 may be a mechanical flow meter, a pressure-based flow meter, an optical flow meter, an electromagnetic flow meter, an ultrasonic flow meter, or the like. Fluid flow monitor may, in real-time or at a predetermined time interval, output the detected flow rate, via a wired or wireless connection to data collector 102.

Effluent monitoring system 113 may be coupled physically to tool 101. Effluent monitoring system may, in real-time or a predetermined time interval, detect characteristics of gas and/or liquid effluent emitted by the tool during, before and/or after operation.

Effluent monitoring system 113 may include flue gas sensors configured to generate one or more outputs indicative of concentrations in the flue gas of one or more of: hydrogen fluoride, hydrogen chloride, ammonia, carbon, ozone or any reagent that can result in a gaseous emission from the tool. Effluent monitoring system 113 may also process the emitted flue gas differently depending on the detected characteristics of the flue gas. For example, effluent monitoring system 113 may provide treatment for excessive causticity in the flue gas caused by a high presence of ammonia. Effluent monitoring system 113 may provide different treatment for excessive acidity in the flue gas caused by a high presence of hydrogen fluoride, as the procedures and treatments for neutralizing excessive ammonia may be different than the treatments for neutralizing excessive hydrogen fluoride.

Effluent monitoring system 113 may include liquid effluent sensors configured to generate one or more outputs indicative of concentrations in the liquid effluent including one or more of: hydrogen fluoride, hydrogen chloride, ammonia, isopropyl alcohol, and any reagent that can result in liquid emission from the tool. Effluent monitoring system 113 may also detect other characteristics of the liquid effluent including: pH, resistivity, temperature, and flow rate. Effluent monitoring system 113 may also process the emitted liquid effluent differently depending on the detected characteristics of the liquid effluent. For example, effluent monitoring system 113 may provide treatment for excessive hydrofluoric acid in the liquid effluent. Effluent monitoring system 113 may provide different treatment for excessive isopropyl alcohol in the liquid effluent, as the procedures and treatments for neutralizing excessive hydrofluoric acid may be different than the treatments for neutralizing excessive isopropyl alcohol.

In some embodiments, fluid flow monitor is coupled to the effluent monitoring system 113 to detect the flow rate of gas and/or liquid effluents in real-time or a predetermined time interval. Effluent monitoring system 113 may also include a leak detector. The leak detector may indicate when there is a leak in the effluent monitoring system 113 and generate a corresponding visual or audio alarm.

Laptop 111 is optionally connected to data collector 102 via a wireless (or wired) connection. Laptop 111 may be used to program and configure data collector 102 operation parameters. Operation parameters may include: which sensors the data collector monitors, a predetermined upper and/or lower threshold for error detection, the type of alarm given when a predetermined threshold is breached, and the like. For example, laptop 111 may configure data collector 102 to only read output from sensors corresponding to the detection of hydrofluoric and hydrochloric acid. Then laptop 111 may configure data collector 102 to create a visual and/or audible alert that activates when the detected amount of hydrofluoric or hydrochloric acid reaches above a certain level.

Data collector 102 may be implemented using any standard computer equipment including but not limited to: a Real-Time CompactRIO as provided by National Instruments, a computer, a field programmable gate array, application specific integrated circuit, and the like.

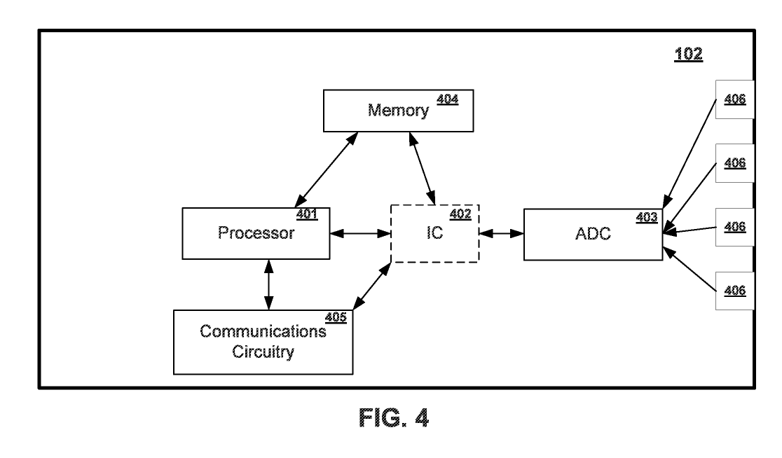

An embodiment of data collector 102 is shown in FIG. 4. Data collector 102 may include input/output ports 406 to receive communications from various tools, sensors, and monitors utilized by the semiconductor fabrication process. In one embodiment, data collector 102 receives, via input/output ports 406, communications from tool 101, energy monitor 103, flow monitor 104, and/or effluent monitoring system 113. Outputs from various tools, sensors, and monitors may be output in analog format. As a result, communications may comprise, at least partially, analog signals. Analog signals may be input into an analog to digital converter (ADC) 403. The converted communications may be input into integrated circuit (IC) 402 for data processing and/or analysis. IC 402 may be implemented as an application specific integrated circuit, a field programmable gate array, and the like. Processor 401 may utilize communication circuitry 405, to transmit information, using wired or wireless communication, to network switch 106 (see FIG. 1). Transmitted information may include results of data processing and/or analysis performed by IC 402, results from ADC 403, original communications received via input/output ports 406, and the like. Memory 404 is configured to store received communications, operating systems, and other data.

In some embodiments, data collector 102 may perform analysis on received communications from various tools, sensors, and monitors with which data collector 102 is associated. Analysis may be performed in real-time or at a predetermined time interval. Performing analysis may include determining certain past and real-time characteristics of a particular tool. For example, characteristics of one or more tools may include the history and real-time detection of the following: ionic impurities; metallic impurities; organic impurities; particle levels (e.g. alkaline, sodium, potassium, nickel, cobalt, iron, aluminum, potassium, indium, gallium, arsenic, boron, metals, and the like); stress cracking, quantities of gas and liquid chemicals (e.g. undesired quantities); particle defects (e.g. extra and/or missing particles). The data collector 102 may implement any number of known signal processing algorithms (e.g. Fourier transforms, Laplace transforms, and the like).

By gathering and analyzing past and real-time data, data collector 102 may predict certain occurrences affecting the tool and the fabrication facility. For example, if the data collector begins to receive real-time information from a sensor or monitor associated with a CMP tool indicating an unwanted temperature increase in the CMP, it could indicate that the CMP tool might fail soon. The polishing process in the CMP is a very temperature sensitive process, and if the temperature is not properly maintained during operation it may lead to faulty operation. Prediction of misoperation in the CMP would allow preventive maintenance and would prevent yield loss in the semiconductor manufacturing process.

Data collector 102 may also be used to create a real-time feedback control system. For example, if the data collector begins to receive real-time information from a sensor or monitor associated with a Radio corporation of America (RCA) clean tool indicating an excessive amount of ammonium hydroxide the data collector may send a signal to the RCA clean tool to modify its operations to correct the problem. Such modification may include: commanding the RCA clean tool to shut down, modifying the amount of ammonium hydroxide input into the RCA clean tool, or the like. In another example, if the data collector begins to receive real-time information from a sensor or monitor related to the liquid effluent of an etching tool indicating the levels of hydrofluoric acid the data collector may send a signal to a valve to send the liquid effluent to various locations depending on the detected level of hydrofluoric acid.

Returning to FIG. 1, semiconductor tool data collection unit 105 is partly comprised of one or more of the following: tool 101, data collector 102, energy monitor 103, effluent monitoring system 113, and fluid flow monitor 104. Semiconductor tool data collection unit 105 may also include other sensors, monitors, and devices that detect various characteristics of tool 101. There may be several semiconductor tool data collection units, where each individual semiconductor tool data collection unit corresponds with a different semiconductor tool. In some embodiments, a semiconductor tool data collection unit may be implemented on supply lines or storage containers for various liquids and/or gases supplied to a tool, such that the sensors and monitors in the semiconductor data collection unit indicate remaining quantities of the liquids and/or gases.

Semiconductor tool data collection unit 105 and other semiconductor tool data collection units may communicate with network switch 106. Network switch 106 may be implemented by any standard computer equipment including but not limited to: Cisco Catalyst, a computer, a server, and the like. Network switch 106 may contain several input ports capable of receiving wired or wireless communication. For example, input ports may include: RJ-45 connectors for receiving Ethernet cables, WAN/LAN/PAN ports for receiving communications over a network, and the like. Network switch 106 outputs received communications from the semiconductor tool data collection units to servers 107.

Servers 107 may be implemented by more or one computers, databases, or the like. Servers 107 may store received communications and/or perform analysis on the received communication. Analysis may be performed in real-time or at a predetermined time interval. The analysis performed by servers 107 may then be stored by servers 107. Any stored information on servers 107 may be backed-up in real time or at predetermined time intervals to cloud server 108. In one embodiment, semiconductor tool data collection unit 105, semiconductor fabrication tool 101, energy monitor 103, fluid flow monitor 104, effluent monitor 113, the network switch 106, and servers 107 are physically located inside a semiconductor fabrication facility. In such an embodiment, cloud server 108 is located remotely from the semiconductor fabrication facility to create a second storage location.

Servers 107 may receive communication from semiconductor tool data collection unit 105 that details communications from various tools, sensors, and monitors. In some embodiments, servers 107 perform analysis on received communications. Performing analysis may include determining certain past and real-time characteristics of a particular tool. For example, characteristics of one or more tools may include the history and real-time detection of the following: ionic impurities; metallic impurities; organic impurities; particle levels; stress cracking, quantities of gas and liquid chemicals; and/or particle defects. In other embodiments, servers 107 may simply receive and store communications from various tools, sensors, and monitors without performing any analysis.

In some embodiments, servers 107 may perform analysis on communications from several semiconductor tool data collection units to determine past, real-time, and future characteristics of particular processes in the fabrication facility. Server 107 may utilize data gathered about multiple tools to determine past, real-time, and further characteristics of the fabrication facility as a whole. In one embodiment, characteristics of processes and/or the whole fabrication facility may include history, detection and/or prediction of the following: yield-analysis information; root-cause analysis information corresponding to the yield-analysis information; semiconductor performance information; defect level information; and particle contamination information.

By gathering and analyzing past and real-time information, servers 107 could be used to predict characteristics that could improve yield. For example, if servers 107 begin to receive information from a semiconductor tool data collection unit attached to a CMP tool that indicates an unwanted temperature increase in the CMP it could indicate that the CMP tool might fail soon, because polishing in the CMP is a very temperature sensitive process. Such a failure by the CMP would also affect the yield of the semiconductor fabrication facility.

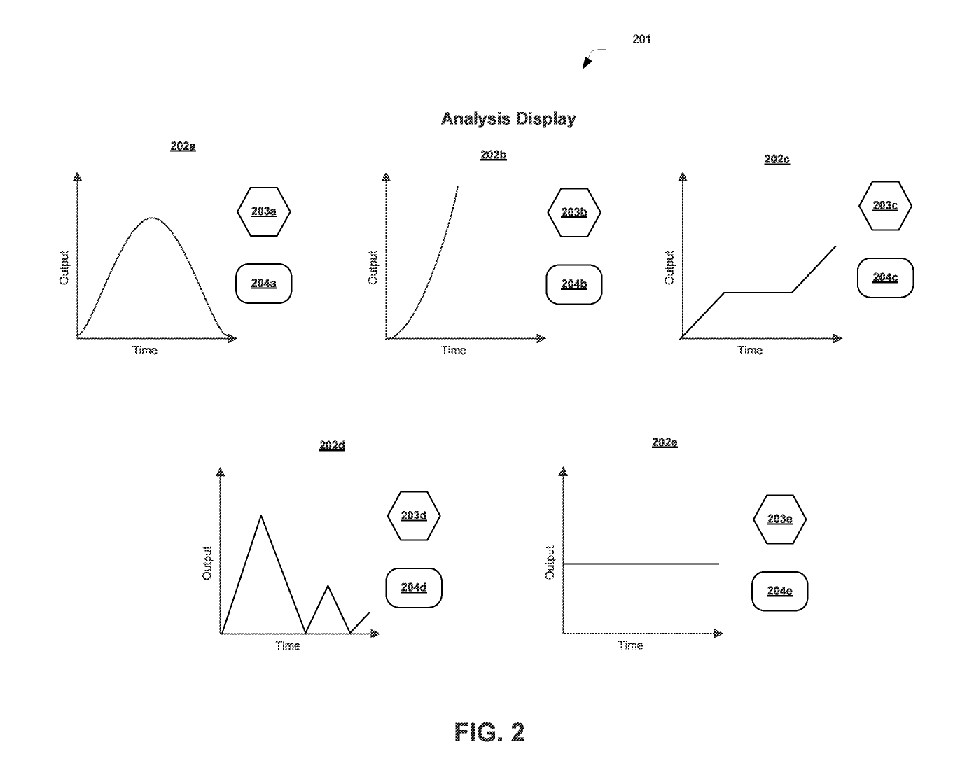

Servers 107 can be configured to communicate with user 112 via a wireless or wired communication protocol (e.g. Ethernet). In some embodiments firewall 109 is positioned between server 107 and network 110 to provide secure communication between user 112 and servers 107. Communications between user 112 and servers 107 may be encrypted using known symmetric or asymmetric cryptography algorithms. Network 110 may be any public or private network such as a Local Area Network (LAN), Wide Area Network (WAN), Public Access Network (PAN) (e.g. the Internet). User 112 may have to provide authentication parameters (e.g. username and password) to an access portal to access particular information corresponding to particular aspects of the fabrication facility. In one embodiment, a user may be only authenticated to view information corresponding to a particular tool, while another user may be authenticated to view information about one or more tools. User 112 may be remote or local to server 107. User 112 may be a person utilizing a user display device that displays information using user interface 201 (see FIG. 2). User 112 may be one or more users.

User 112 may access servers 107 to view or download stored information pertaining to one or more tools, one or more semiconductor fabrication processes, or the semiconductor fabrication facility as a whole. Using servers 107, user 112 has real-time access to information transmitted by one or more semiconductor tool data collection units; analysis performed by one or more semiconductor tool data collection units; analysis performed by servers; and the like. In some embodiments, semiconductor fabrication tool data collection system 100 enables remote monitoring of one or more tools and processes in real-time without having to be physically in the fabrication facility. For example, Company A owns and operates a semiconductor fabrication facility. Company B manufacturers and operates a particular semiconductor tool used in a photolithography process. Company C receives a finished semiconductor from the semiconductor fabrication facility. A member of Company B may be authenticated to view only real-time information corresponding to the semiconductor tool owned by Company B. On the other hand, a member of Company C may be authenticated to view real-time information corresponding to the whole semiconductor fabrication process.

FIG. 2 is an illustration of an embodiment of an analysis display utilizing user interface 201. User interface 201 may be the screen of a user display device that allows user 112 to display information obtained from server 107 and/or data collector 102. The user display device may be a PDA, computer, mobile computer, laptop computer, cellular phone, mobile phone, tablet, and the like. Graphs 202a-e show an illustrative example of information obtained from servers 107. Graphs 202a-e display a particular output over a defined time interval. For example, graph 202a may display temperature of a CMP tool over a three hour period. Buttons 203a-e allow user 112 to change the output displayed on graphs 202a-e, respectively, as well as change various other chart properties, including but not limited to graph type (e.g. bar, line, pie, etc.), threshold level for alert notifications, and the time interval for the chart. Alarms may be visually represented on the user interface 201 as alarms 204a-e, wherein each alarm 204a-e corresponds to a particular output. Alarms 204a-e may be generated if a certain predetermined condition has occurred. For example, graph 202c represents the yield of a semiconductor manufacturing facility over 10 months, and alarm 204c may be activated when yield (e.g. output) falls below a certain level. Alarms 204a-e may be audible in addition to, or alternatively to, the visual alarm. As shown, user interface 201 displays information obtained from servers 107 using graphics. However, it is within the scope of the invention to display information in a plurality of forms, such as a word document.

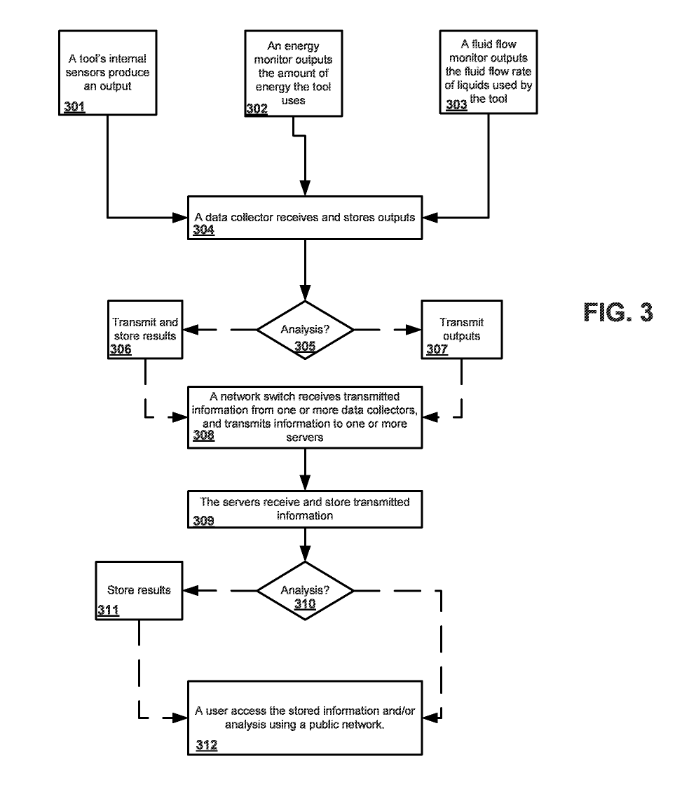

FIG. 3 demonstrates an exemplary method of using the semiconductor fabrication tool data collection system. At step 301, a tool's sensors produce, in real-time or a predetermined time interval, one or more outputs indicating particular characteristics about the tool. At step 302, an energy monitor produces, in real-time or a predetermined time interval, one or more outputs indicating particular energy and/or power characteristics about the tool. At step 303, a fluid flow monitor produces, in real-time or a predetermined time interval, one or more outputs indicating particular fluid flow rate of fluids used, coming into, and/or being output by the tool. Steps 301-303 may occur synchronously or asynchronously. There also may be other steps similar to steps 301-303 if the semiconductor fabrication tool data collection system contains other sensors or monitors (e.g. an effluent monitoring system) to detect other characteristics of the tool or semiconductor fabrication facility processes. At step 304, a data collector receives and stores the outputs from steps 301-303. At step 305, a decision is made regarding whether the data collector should perform analysis on the received outputs (step 306) or simply transmit the outputs (step 307) to a network switch. If step 306 is reached, in addition to performing analysis, the data collector may also store the results of the analysis. Optionally, the data collector may also transmit the outputs used for the analysis along with the results of the analysis. At step 308, information (i.e. the results of analysis done in step 306 and/or the transmitted outputs from step 307) is sent from the data collector to the network switch. The network switch may also receive information from several data collectors. The network switch transmits all received information to one or more servers. At step 309, the servers receive and store the transmitted information. At step 310, a decision is made regarding whether the servers should perform analysis on the received information (step 311). If step 311 is reached, in addition to performing analysis, the server may also store the results of the analysis. The server may also perform analysis on received information even if the data collector has performed a prior analysis. For example, the data collector may perform analysis on received outputs to detect the amount of hydrofluoric acid in an etching tool, and the server may perform a similar analysis on information received from multiple data collectors to detect the amount of hydrofluoric acid that is present throughout a photolithographic process, which may span multiple tools. At step 312, regardless of whether an analysis was performed by the data collector and/or the server, a user may access information stored in the servers using a public access network. All steps may be performed in real-time or at a predetermined time interval. In some embodiments, the user is able to monitor and evaluate the whole semiconductor fabrication process and/or operation of specific tools in real-time without physically being located in the fabrication facility. In other embodiments the method as described in FIG. 3 allows for reduced shutdown time when a fabrication facility installs new tools or is reconfiguring current tools by allowing users real-time information.

### III. Exemplary Processors and Computing Devices

Systems and methods disclosed herein may include one or more programmable processors, processing units and computing devices having associated therewith executable computer-executable instructions held or encoded on one or more non-transitory computer readable media, RAM, ROM, hard drive, and/or hardware. In exemplary embodiments, the hardware, firmware and/or executable code may be provided, for example, as upgrade module(s) for use in conjunction with existing infrastructure (for example, existing devices/processing units). Hardware may, for example, include components and/or logic circuitry for executing the embodiments taught herein as a computing process.

Displays and/or other feedback means may also be included, for example, for rendering a graphical user interface, according to the present disclosure. The displays and/or other feedback means may be stand-alone equipment or may be included as one or more components/modules of the processing unit(s).

The actual computer-executable code or control hardware that may be used to implement some of the present embodiments is not intended to limit the scope of such embodiments. For example, certain aspects of the embodiments described herein may be implemented in code using any suitable programming language type such as, for example, the MATLAB technical computing language, the LABVIEW graphical programming language, assembly code, C, C# or C++ using, for example, conventional or object-oriented programming techniques. Such computer-executable code may be stored or held on any type of suitable non-transitory computer-readable medium or media, such as, a magnetic or optical storage medium.

As used herein, a “processor,” “processing unit,” “computer” or “computer system” may be, for example, a wireless or wire line variety of a microcomputer, minicomputer, server, mainframe, laptop, personal data assistant (PDA), wireless e-mail device (for example, “BlackBerry,” “Android” or “Apple,” trade-designated devices), cellular phone, pager, processor, fax machine, scanner, or any other programmable device configured to transmit and receive data over a network. Computer systems disclosed herein may include memory for storing certain software applications used in obtaining, processing and communicating data. It can be appreciated that such memory may be internal or external to the disclosed embodiments. The memory may also include a non-transitory storage medium for storing computer-executable instructions or code, including a hard disk, an optical disk, floppy disk, ROM (read only memory), RAM (random access memory), PROM (programmable ROM), EEPROM (electrically erasable PROM), flash memory storage devices, or the like.

In describing exemplary embodiments, specific terminology is used for the sake of clarity. For purposes of description, each specific term is intended to; at least, include all technical and functional equivalents that operate in a similar manner to accomplish a similar purpose. In addition, in some instances where a particular exemplary embodiment includes a plurality of system elements or method steps, those elements or steps may be replaced with a single element or step. Likewise, a single element or step may be replaced with a plurality of elements or steps that serve the same purpose. Further, where parameters for various properties are specified herein for exemplary embodiments, those parameters may be adjusted up or down by 1/20th, 1/10th, ⅕th, ⅓rd, ½nd, and the like, or by rounded-off approximations thereof, unless otherwise specified. Moreover, while exemplary embodiments have been shown and described with references to particular embodiments thereof, those of ordinary skill in the art will understand that various substitutions and alterations in form and details may be made therein without departing from the scope of the invention. Further still, other aspects, functions and advantages are also within the scope of the invention.

Exemplary flowcharts are provided herein for illustrative purposes and are non-limiting examples of methods. One of ordinary skill in the art will recognize that exemplary methods may include more or fewer steps than those illustrated in the exemplary flowcharts, and that the steps in the exemplary flowcharts may be performed in a different order than shown.

Blocks of the block diagram and the flow chart illustrations support combinations of means for performing the specified functions, combinations of steps for performing the specified functions and program instruction means for performing the specified functions. It will also be understood that some or all of the blocks/steps of the circuit diagram and process flowchart, and combinations of the blocks/steps in the circuit diagram and process flowcharts, can be implemented by special purpose hardware-based computer systems that perform the specified functions or steps, or combinations of special purpose hardware and computer instructions. Exemplary systems may include more or fewer modules than those illustrated in the exemplary block diagrams.

Many modifications, combinations and other embodiments of the inventions set forth herein will come to mind to one skilled in the art to which these embodiments of the invention pertain having the benefit of the teachings presented in the foregoing descriptions and the associated drawings. Therefore, it is to be understood that the embodiments of the invention are not to be limited to the specific embodiments disclosed and that modifications, combinations and other embodiments are intended to be included within the scope of the appended claims. Although specific terms are employed herein, they are used in a generic and descriptive sense only and not for purposes of limitation.

What is claimed is:

1. A fabrication data collection system comprising:
a semiconductor tool data collection unit comprising: a data collector, a semiconductor fabrication tool, an energy monitor, and a fluid flow monitor;
wherein the semiconductor fabrication tool includes sensors to output tool characteristics, and the tool characteristics output is communicated to the data collector;
wherein the energy monitor outputs an amount of energy used by the semiconductor fabrication tool, and the energy monitor output is communicated to the data collector;
wherein the fluid flow monitor outputs a fluid flow rate of the semiconductor fabrication tool, and the fluid flow rate output is communicated to the data collector;
wherein the semiconductor tool data collection unit is configured to communicate the outputs to one more servers using a network switch, wherein the network switch is configured to receive a communication from one or more semiconductor tool data collection units;
wherein the servers are configured to store the outputs and/or perform analysis on the one or more communications from the one or more semiconductor tool data collection units, and to connect to a public network through a secure firewall, such that one or more authorized users are remotely able to access information on the servers though the public network via the secure firewall.

2. The fabrication data collection system of claim 1 further comprising a liquid effluent monitoring system that outputs properties of liquid effluent emitted by the semiconductor fabrication tool, wherein the properties of liquid effluent are communicated to the data collector.

3. The fabrication data collection system of claim 1 further comprising a gas effluent monitoring system that outputs properties of gas effluent emitted by the semiconductor fabrication tool, wherein the properties of gas effluent are communicated to the data collector.

4. The fabrication data collection system of claim 1, wherein the servers perform analysis by taking as an input one or more outputs from one or more semiconductor tool data collection units, and based on the one or more inputs, generate and store real-time reports detailing past and current information relating to one or more semiconductor fabrication tools.

5. The fabrication data collection system of claim 4, wherein the past and current information includes at least one of: detection of ionic impurities; detection of metallic impurities; detection of organic impurities; detection of particle levels; detection of stress cracking; detection of undesired quantities of gas and liquid chemicals; detection of particle defects.

6. The fabrication data collection system of claim 1, wherein the semiconductor tool data collection unit, the semiconductor fabrication tool, the energy monitor, the fluid flow monitor, the network switch, and the servers are physically located inside a semiconductor fabrication facility.

7. The fabrication data collection system of claim 6, wherein the servers perform analysis on the one or more outputs from one or more semiconductor tool data collection units, and generate and store real-time reports detailing past and current operating information of the semiconductor fabrication facility.

8. The fabrication data collection system of claim 7, wherein the past and current operating information of the semiconductor fabrication facility comprises data from at least two different semiconductor tool data collection units.

9. The fabrication data collection system of claim 8, wherein the reports detailing past and current operating information of the semiconductor facility include one or more of: yield-analysis information; root-cause analysis information corresponding to the yield-analysis information; device performance information; defect level information; and particle contamination information.

10. The fabrication data collection system of claim 6, further comprising:
one or more cloud servers located outside the semiconductor fabrication facility, wherein the cloud servers are configured to connect to the servers to remotely backup and store information present on the server.

11. The fabrication data collection system of claim 1, further comprising a user access portal, wherein an authorized user accesses information on the servers, via the access portal, that was produced by the semiconductor tool data collection in connection with the authorized user's semiconductor production.

12. The fabrication data collection system of claim 1, wherein semiconductor tool data collection unit is configured to store and/or perform analysis on the outputs, and generate and store real-time reports detailing past and current information relating to one or more semiconductor fabrication tools.

13. The fabrication data collection system of claim 12, wherein the past and current information includes one or more of: detection of ionic impurities; detection of metallic impurities; detection of organic impurities; detection of particle levels; detection of stress cracking, detection of quantities of gas and liquid chemicals; and particle defects.

14. The fabrication data collection system of claim 1, further comprising a plurality of supply monitors that output quantities of various liquids and/or gases supplied to the semiconductor fabrication tool, wherein the quantities output is communicated to the data collector.

15. The fabrication data collection system of claim 1, wherein the sensors of the semiconductor fabrication tool are provided by the tool manufacturer or a party who services the semiconductor fabrication tool.
